(19) United States
(12) Patent Application Publication
(10) Pub. No.: US 2017/0317187 A1
(43) Pub. Date: Nov. 2, 2017

(54) Uniform Layers Formed with Aspect Ratio Trench Based Processes

(71) Applicant: INTEL CORPORATION, Santa Clara, CA (US)

(72) Inventors: Sanaz K. GARDNER, Hillsboro, OR (US); Willy RACHMADY, Beaverton, OR (US); Matthew V. METZ, Portland, OR (US); Gilbert DEWEY, Hillsboro, OR (US); Jack T. KAVALIEROS, Portland, OR (US); Chandra S. MOHAPATRA, Beaverton, OR (US); Anand S. MURTHY, Portland, OR (US); Nadia RAHHAL-ORABI, Hillsboro, OR (US); Nancy M. ZELICK, Portland, OR (US); Marc C. FRENCH, Forest Grove, OR (US); Tahir GHANI, Portland, OR (US)

(21) Appl. No.: 15/528,793

(22) PCT Filed: Dec. 23, 2014
(86) PCT No.: PCT/US2014/072143

§ 371 Date: May 23, 2017

(51) Int. Cl. H01L 29/66; H01L 29/786; H01L 29/423; H01L 29/06; H01L 27/088; H01L 21/8234; H01L 21/02

(52) U.S. Cl. CPC H01L 29/66742; H01L 29/78696; H01L 29/78681; H01L 29/66522; H01L 29/42392; H01L 21/02392; H01L 27/088; H01L 21/823412; H01L 21/02603; H01L 21/02546; H01L 29/0673

(57) ABSTRACT

An embodiment includes a device comprising: first and second fins adjacent one another and each including channel and subfin layers, the channel layers having bottom surfaces directly contacting upper surfaces of the subfin layers; wherein (a) the bottom surfaces are generally coplanar with one another and are generally flat; (b) the upper surfaces are generally coplanar with one another and are generally flat; and (c) the channel layers include an upper material and the subfin layers include a lower III-V material different from the upper III-V material. Other embodiments are described herein.

### TECHNICAL FIELD

Embodiments of the invention are in the field of semiconductor devices and, in particular, transistors formed using aspect ratio trench (ART) techniques.

### BACKGROUND

Epitaxy refers to the deposition of a crystalline overlayer on a crystalline substrate. The overlayer is called an epitaxial (EPI) film or EPI layer. EPI films may be grown from gaseous or liquid precursors. Because the substrate acts as a seed crystal, the deposited film may lock into one or more crystallographic orientations with respect to the substrate crystal. If the overlayer either forms a random orientation with respect to the substrate or does not form an ordered overlayer, it is termed non-EPI growth. If an EPI film is deposited on a substrate of the same composition, the process is called homoepitaxy; otherwise it is called heteroepitaxy which is a kind of epitaxy performed with materials that are different from each other. In heteroepitaxy, a crystalline film grows on a crystalline substrate or film of a different material. Heteroepitaxy technology is often used to grow crystalline films of materials for which crystals cannot otherwise be obtained and to fabricate integrated crystalline layers of different materials. Examples include aluminium gallium indium phosphide (AlGaInP) on gallium arsenide (GaAs) and the like.

Epitaxy is used in silicon-based manufacturing processes for bipolar junction transistors (BJTs) and modern complementary metal-oxide-semiconductors (CMOS). Epitaxy may be used in the formation of non-planar transistors such as a FinFET. A FinFET is a transistor built around a thin strip of semiconductor material (referred to as the “fin”). The transistor includes the standard field effect transistor (FET) nodes/components: a gate, a gate dielectric, a source region, and a drain region. The conductive channel of the device resides on the outer sides of the fin beneath the gate dielectric. Specifically, current runs along both “sidewalls” of the fin as well as along the top side of the fin. Because the conductive channel essentially resides along the three different outer, planar regions of the fin, such a FinFET is typically referred to as a “tri-gate” FinFET. Other types of FinFETs exist (such as “double-gate” FinFETs in which the conductive channel principally resides only along both sidewalls of the fin and not along the top side of the fin).

Manufacturing issues for EPI layer growth include control of the amount and uniformity of the EPI layer's resistivity and thickness.

### BRIEF DESCRIPTION OF THE DRAWINGS

Features and advantages of embodiments of the present invention will become apparent from the appended claims, the following detailed description of one or more example embodiments, and the corresponding figures. Where considered appropriate, reference labels have been repeated among the figures to indicate corresponding or analogous elements.

FIG. 1 includes an image of non-uniform EPI layers.

FIG. 2 includes an image of non-uniform EPI layers.

FIGS. 3(a)-(d) depict a process for forming uniform EPI layers in an embodiment of the invention.

FIGS. 4(a)-(d) depict a process for forming uniform EPI layers in an embodiment of the invention.

FIGS. 5(a)-(b) include images of uniform EPI layers in an embodiment of the invention.

### DETAILED DESCRIPTION

Reference will now be made to the drawings wherein like structures may be provided with like suffix reference designations. In order to show the structures of various embodiments more clearly, the drawings included herein are diagrammatic representations of semiconductor/circuit structures. Thus, the actual appearance of the fabricated integrated circuit structures, for example in a photomicrograph, may appear different while still incorporating the claimed structures of the illustrated embodiments. Moreover, the drawings may only show the structures useful to understand the illustrated embodiments. Additional structures known in the art may not have been included to maintain the clarity of the drawings. For example, not every layer of a semiconductor device is necessarily shown. “An embodiment”, “various embodiments” and the like indicate embodiment(s) so described may include particular features, structures, or characteristics, but not every embodiment necessarily includes the particular features, structures, or characteristics. Some embodiments may have some, all, or none of the features described for other embodiments. “First”, “second”, “third” and the like describe a common object and indicate different instances of like objects are being referred to. Such adjectives do not imply objects so described must be in a given sequence, either temporally, spatially, in ranking, or in any other manner. “Connected” may indicate elements are in direct physical or electrical contact with each other and “coupled” may indicate elements co-operate or interact with each other, but they may or may not be in direct physical or electrical contact.

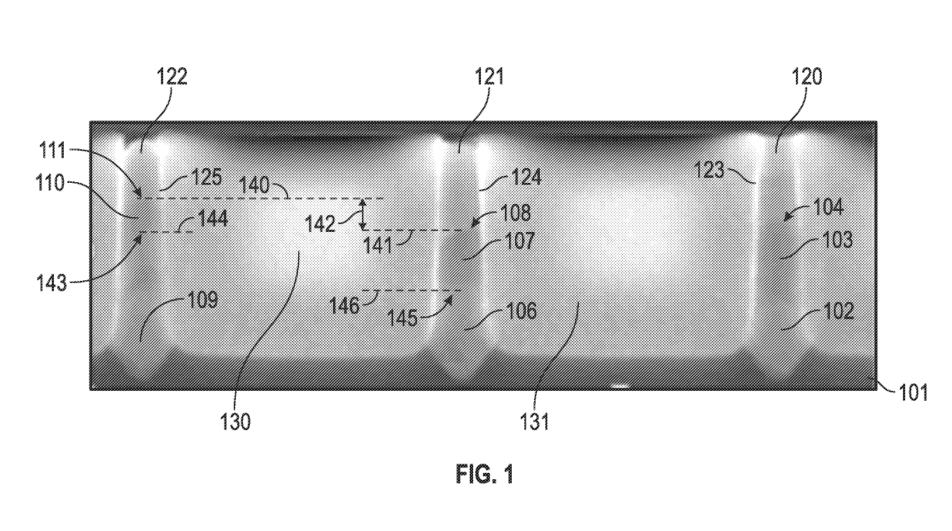

As mentioned above, manufacturing issues for EPI layer growth include control of the amount and uniformity of the EPI layer's resistivity and thickness. FIG. 1 includes an image of non-uniform EPI layers grown on substrate 101. FIG. 1 includes a III-V material stack formed within shallow trench isolation (STI) 130, 131, such as an oxide. Namely, InGaAs layers 103, 107, 110 were grown in-situ with InP portions 102, 106, 109 under the InGaAs layers and InP portions 120, 121, 122 portions on the InGaAs layers. All of the InGaAs and InP layers are formed within trenches 123, 124, 125 formed using aspect ratio trench (ART) processes. While “InGaAs” is often used herein, “InGaAs” includes InₓGa₁₋ₓAs where x is between 0 and 1 thereby including, in various embodiments, InAs and in other embodiments GaAs.

ART is based on threading dislocations that propagate upwards at a specific angle. In ART a trench is made with a high enough aspect ratio such that the defects terminate on the sidewall of the trench and any layer above the terminations is defect free. More specifically, ART includes trapping defects along the sidewall of a shallow trench isolation (STI) portion by making the height (H) of the trench larger than the width (W) of the trench such that H/W ratio is at least 1.50. This ratio gives the minimum limit for ART to block defects within a buffer layer.

An issue seen in FIG. 1 is the non-uniformity of the InGaAs layers 103, 107, 110. For example, each InGaAs layer has a top surface 104, 108, 111. However, top surface 108 (see horizontal line 141) is not aligned vertically with top surface 111 (see horizontal line 140) by a vertical distance 142. Offset 142 can be problematic and is caused by in situ multilayer III-V ART fins having non-uniform growth within the trenches. For example, offset 142 can lead to sidewalls that become blocked and do not allow for wet etch gate-all-around (GAA) release. More specifically, GAA FETs are similar in concept to FinFETs except that the gate material surrounds the channel region on all sides. Depending on design, GAA FETs can have two or four effective gates. Gate-all-around FETs may be built around nanowires. Offset 142 can pose a problem for a GAA architecture because STI 130 may need to be etched below InGaAs layer bottom surface 143 (see horizontal line 144) to form a gate along surface 143. However, this etching may not go down far enough to also expose InGaAs layer bottom surface 145(see horizontal line 146). Additional problems may concern electrostatic concerns, such as varying performance such as resistance and/or leakage current properties that are brought on by varying sizes of lower fin InP portions that support channel material InGaAs portions.

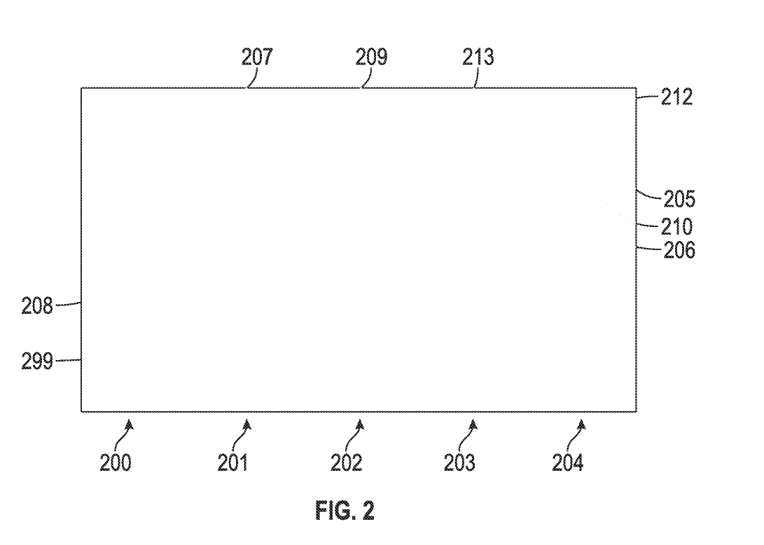

FIG. 2 includes an image of non-uniform EPI layers, however in this figure the non-uniformity is not necessarily between differing heights of layers in differing fins. Instead, FIG. 2 shows the non-uniformity within a single layer. More specifically, Figure two shows various images of a single fin with each image “highlighting” certain components. Image 200 includes a general image of a fin with an InGaAs layer formed between two InP layers. Image 201 highlights areas of In presence 207, 208. Image 202 highlights areas of P presence 209, 210 (which coincide with areas 207, 208 considering these are InP layers). Image 203 highlights an area of Ga presence 206. Image 204 highlights an area of As presence 205 (which coincides with area 206 considering these are InGaAs layers). Notably, Ga and As portions 206, 205 have curved upper surfaces 213, 212 and lower surfaces 211, 210. The unevenness/curvature of any of these surfaces can again be problematic when, for example, trying to form nanoribbon GAA devices and the like.

Thus, Applicant has discovered various problems such as the aforementioned performance and manufacturing issues concerning various forms of unevenness: (1) when layer heights vary from fin to fin, and (2) when a layer height varies within itself (e.g., has a curved top surface).

However, embodiments achieve uniform layers in ART trenches. For example, embodiments provide selective wet etching to uniformly recess subfin materials, such as InP 109. The wet etch may be performed ex-situ (after a layer is grown) as opposed to in situ growth (while a layer is being grown). In other words, after the subfin is formed it is then etched to flatten and even out the top surface of the subfin.

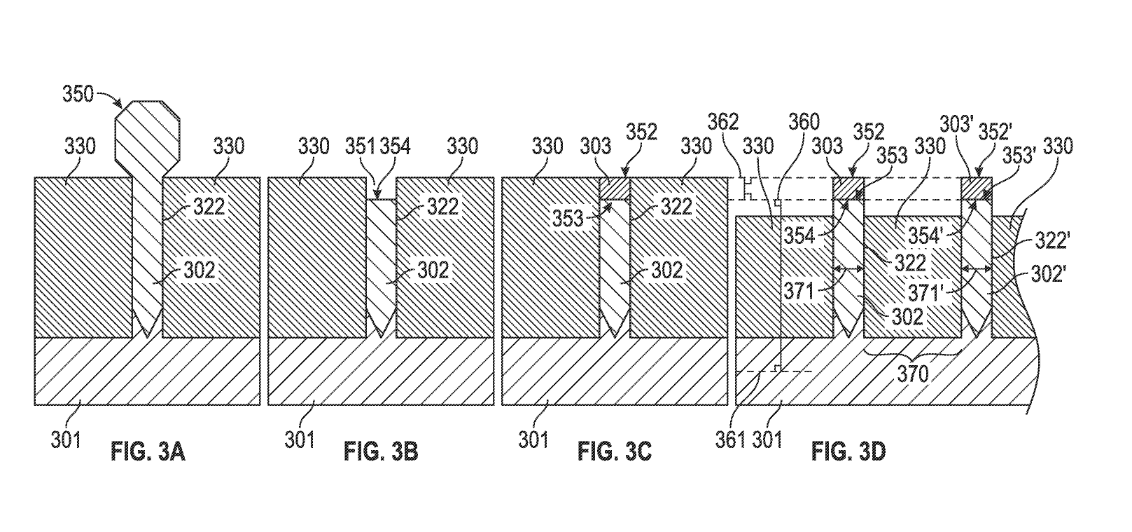

Embodiments also provide selective EPI deposition processes to grow conformally uniform layers of layers, such as III-V materials (e.g., InGaAs layer 110), on recessed III-V materials (e.g., InP portions within a trench (see FIG. 3(b)).

Embodiments further provide bilayer stacks (e.g., InGaAs/InP) inside narrow ART trenches with uniform layer thickness (e.g., InGaAs) across a single fin's width and length.

FIG. 3(a)-(d) depict a process for forming uniform EPI layers in an embodiment of the invention. FIG. 3(a) depicts growth if an InP fin 302, which will eventually serve as subfin support for channel material. Fin 302 is grown on substrate 301 and within ART trench 322 and STI 330. Overgrowth 350 is removed in FIG. 3(b) via InP polishing and InP is further recessed to form recess 351 above subfin portion 302. In FIG. 3(c) InGaAs 303 is then grown within trench 322 and polished to form a flat upper surface 352 and flat lower surface 353 formed atop flat upper surface 354.

In FIG. 3(d) STI 330 is recessed to expose InGaAs layer 303 and subfin 302 within trench 322. FIG. 3(d) further includes a second fin adjacent to the fin that was the focus of FIGS. 3(a)-(c). Specifically, FIG. 3 depicts a device comprising: a first fin structure including a first upper fin portion 303 on a first lower fin portion 302 and a second fin structure including a second upper fin portion 303′ on a second lower fin portion 302′. No other fin structures exist between the first and second fin structures (i.e., within area 370) and first and second fin structures are adjacent to one another. The first and second upper fin portions 303, 303′ have first and second bottom surfaces 353, 353′ that directly contact first and second upper surfaces 354, 354′of the first and second lower fin portions 302, 302′. The first and second bottom surfaces 353, 353′ are generally coplanar with one another and are generally flat. For example, first and second bottom surfaces 353, 353′are each located along horizontal line 360, which is parallel to long axis (horizontal) 361 of substrate 301. The first and second upper surfaces 354, 354′ are generally coplanar with one another and are generally flat (first and second upper surfaces 354, 354′ are each located on line 360). The first and second upper fin structures 303, 303′ include an upper III-V material and the first and second lower fin structures 302, 302′ include a lower III-V material different from the upper III-V material. For example, while many embodiments herein describe 303/302 stacks of InGaAs/InP other embodiments are not so limited and may include, for example, InGaAs/InₓAl₁₋ₓAs, InGaAs/InₓAl₁₋ₓAs/InP, or InGaAs/InP/InₓAl₁₋ₓAs (e.g., where InGaAs includes InₓGa₁₋ₓAs where x is between 0 and 1 and InAlAs includes InₓAl₁₋ₓAs where x is between 0 and 1). In an embodiment stack layers 303/302 and 303′/302′ are epitaxial layers.

The first and second fin structures are at least partially included in first and second trenches 322, 322′. In an embodiment the first and second trenches each have generally equivalent aspect ratios (depth to width) that are at least 2:1. Embodiments may include ratios including 1.4:1, 2.5:1, 3:1 (150 nm:50 nm); 4:1 and the like.

In an embodiment, the first and second upper fin portions 303, 303′ have first and second top surfaces that are generally coplanar with one another, are generally flat (top surfaces 352, 352′ are each located on line 362), and are generally parallel to the substrate (see line 361)and to the first and second bottom surfaces 353, 353′. Top surfaces 352, 352′ may be flat/planar due to polishing.

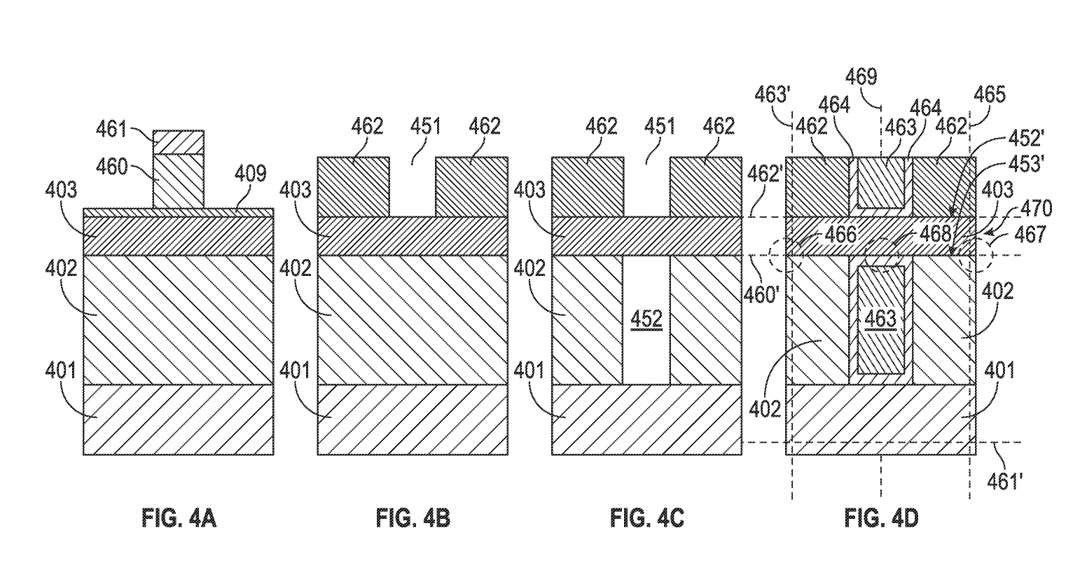

In an embodiment similar to FIG. 4, a fin portion has a top surface that is generally flat (top surface 452′ located on line 462′) and generally parallel to the substrate (see line 461′) and to bottom surface 453′ (located along horizontal line 460′).

In an embodiment, the first and second bottom surfaces 353, 353′ are flat and each extend across entire breadths 371, 371′ of the first and second fin structures.

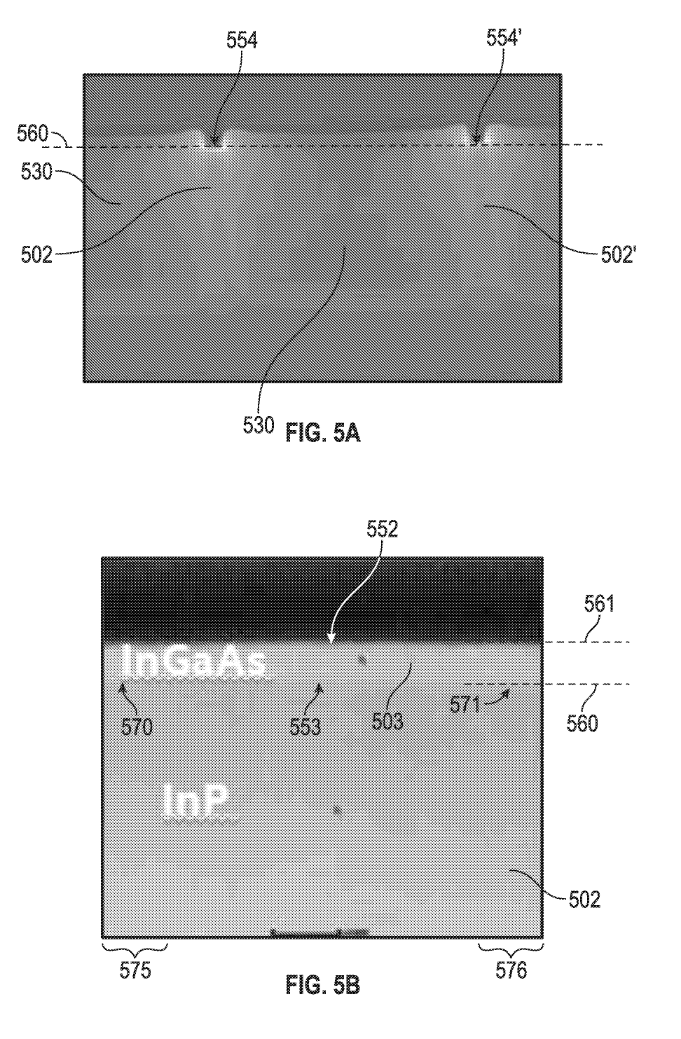

FIGS. 5(a)-(b) include images of uniform EPI layers in an embodiment of the invention. FIG. 5(a) includes STI portions 530 forming trenches that include subfin potions 502, 502′ before any channel portions are filled in recesses 554, 554′. Line 560 is analogous to line 360 of FIG. 3(d) and shows how top surfaces of subfin InP portions 502, 502′ are planar within themselves and with one another and generally parallel to the substrate. Line 561 is analogous to line 362 of FIG. 3(d) and shows how top surface 561 is flat and even. FIG. 5(b) shows a side view of one of the fins of FIG. 5(a) after channel material 503 is added on to subfin 502. Upper and lower surfaces 552, 553 of InGaAs channel material 503 are even, flat and parallel to upper surface 570 of subfin 502.

Thus, FIG. 5(b) shows a first fin structure including a left end portion 575 at a left end of the first fin structure and a right end portion 576 at a right end of the first fin structure. Bottom surface 553 is flat and coplanar from portion 575 to portion 576 and generally parallel to the substrate.

FIGS. 4(a)-(d) depict a process for forming uniform EPI layers in an embodiment of the invention. FIG. 4(a) shows a side view of a fin with InP subfin 402 between substrate 401 and InGaAs channel material 403. Gate patterning has begun with hard mask 461 covering polysilicon 460, which is on dielectric 409. After interlayer dielectric (ILD) 462 is formed in FIG. 4(b), polysilicon is removed to form recess 451. In FIG. 4(c) wet-etch release occurs to remove subfin portions to create recess 452. In FIG. 4(d) recesses 451, 452 are filled with metal gate portions 463 and high dielectric constant (high K) gate dielectric 464. By doing so nanoribbon 470 is formed to create GAA structures.

Thus, embodiments provide a situation where InP (or some other III-V materials) is grown within an ART trench, followed by a uniform wet etch recess of InP within the trench. Subsequently, an even platform is provided for ex-situ InGaAs (or some other III-V materials) regrowth and polish. This results in uniform InGaAs layers which not only have better device performance but also provide downstream wet-etch release options for GAA architectures.

In an embodiment a multilayer III-V FinFET structure is formed using, for example, the exposed materials 303 of FIG. 3(d) (i.e., forming a gate structure over channel material 303). The embodiment has uniform layers of different materials embedded in fins for forming tri-gate transistors. In an embodiment, a uniform InₓAl₁₋ₓAs (where x is between 0 and 1) subfin layer may be grown between InGaAs (channel) and InP (subfin) layers and this layer will be useful shutting off/decreasing sub-fin leakage in III-V trigate transistors (therefore allowing further gate length (Lg) scaling).

While figures like FIG. 3(d) show InGaAs atop InP these figures are for instructional purposes and devices may include additional layers, such as an InP layer atop the InGaAs layer.

Various embodiments include a semiconductive substrate. Such a substrate may be a bulk semiconductive material that is part of a wafer. In an embodiment, the semiconductive substrate is a bulk semiconductive material as part of a chip that has been singulated from a wafer. In an embodiment, the semiconductive substrate is a semiconductive material that is formed above an insulator such as a semiconductor on insulator (SOI) substrate. In an embodiment, the semiconductive substrate is a prominent structure such as a fin that extends above a bulk semiconductive material.

The following examples pertain to further embodiments.

Example 1 includes a device comprising: a first fin structure including a first upper fin portion on a first lower fin portion; a second fin structure including a second upper fin portion on a second lower fin portion; wherein (a) no other fin structures exist between the first and second fin structures and first and second fin structures are adjacent one another; (b) the first and second upper fin portions have first and second bottom surfaces that directly contact first and second upper surfaces of the first and second lower fin portions; (c) the first and second bottom surfaces are generally coplanar with one another and are generally flat; (d) the first and second upper surfaces are generally coplanar with one another and are generally flat; and (e) the first and second upper fin structures include an upper III-V material and the first and second lower fin structures include a lower III-V material different from the upper III-V material.

In example 2 the subject matter of example 1 can optionally include wherein the first and second fin structures are at least partially included in first and second trenches.

In example 3 the subject matter of examples 1-2 can optionally include wherein the first and second trenches each have generally equivalent aspect ratios (depth to width) that are at least 2:1.

In example 4 the subject matter of examples 1-3 can optionally include wherein the upper III-V material includes InGaAs. In an embodiment the subject matter of the Examples 1-3 can optionally include wherein the upper III-V material includes InₓGa₁₋ₓAs where x is between 0 and 1 thereby including, in various embodiments, InAs and in other embodiments GaAs.

In example 5 the subject matter of examples 1-4 can optionally include wherein the lower III-V material includes InP.

In example 6 the subject matter of examples 1-5 can optionally include wherein the first and second upper fin structures and the first and second lower fin structures are epitaxial layers.

In example 7 the subject matter of examples 1-6 can optionally include a substrate, wherein the first and second bottom surfaces are generally parallel to a long axis of the substrate.

In example 8 the subject matter of examples 1-7 can optionally include wherein (a) the first fin structure includes a left end portion at a left end of the first fin structure and a right end portion at a right end of the first fin structure; (b) the left end portion includes a left bottom surface portion of the first bottom surface and the right end portion includes a right bottom surface portion of the first bottom surface; and (c) the left and right bottom surface portions are coplanar with one another and generally parallel to the substrate.

In example 9 the subject matter of examples 1-8 can optionally include wherein the first and second upper fin portions have first and second top surfaces that are generally coplanar with one another, are generally flat, and are generally parallel to the substrate and to the first and second bottom surfaces.

In example 10 the subject matter of examples 1-9 can optionally include wherein the first and second bottom surfaces each extend across entire breadths of the first and second fin structures.

In example 11 the subject matter of examples 1-10 can optionally include wherein the first and second upper fin portions are included in first and second nanoribbons.

In example 12 the subject matter of examples 1-11 can optionally include wherein the first and second nanoribbons are included in gate-all-around devices.

Example 13 includes a device comprising: a first fin structure including a first upper fin portion on a first lower fin portion; a second fin structure including a second upper fin portion on a second lower fin portion; wherein (a) the first and second upper fin portions have first and second bottom surfaces that directly contact first and second upper surfaces of the first and second lower fin portions; (b) the first and second bottom surfaces are generally coplanar with one another and are generally flat; (c) the first and second upper surfaces are generally coplanar with one another and are generally flat; (d) the first and second upper fin structures include an upper III-V material and the first and second lower fin structures include a lower III-V material different from the upper III-V material; and (e) a first vertical axis intersects first portions of the first bottom surface and the first upper surface, a second vertical axis intersects second portions of the first bottom surface and the first upper surface, and a third vertical axis, located between the first and second vertical axes, intersects a third portions of the first bottom surface and a gate but no portion of the first upper surface.

For example, in FIG. 4(d) axis 463′ intersects, at location 466, a lower surface of nanoribbon 470 and an upper surface of subfin 402. Axis 465 intersects, at location 467, a lower surface of nanoribbon 470 and an upper surface of subfin 402. Axis 469 intersects, at location 468, a lower surface of nanoribbon 470 and gate materials 463, 464 but not an upper surface of subfin 402.

In example 14 the subject matter of example 13 can optionally include wherein the first and second fin structures are at least partially included in first and second trenches that each have generally equivalent aspect ratios (depth to width) that are at least 2:1.

In example 15 the subject matter of examples 13-14 can optionally include a substrate, wherein the first and second bottom surfaces are generally parallel to a long axis of the substrate.

In example 16 the subject matter of examples 13-15 can optionally include wherein (a) the first fin structure includes a left end portion at a left end of the first fin structure and a right end portion at a right end of the first fin structure; (b) the left end portion includes a left bottom surface portion of the first bottom surface and the right end portion includes a right bottom surface portion of the first bottom surface; and (c) the left and right bottom surface portions are coplanar with one another and generally parallel to the substrate.

In example 17 the subject matter of examples 13-16 can optionally include wherein the first and second bottom surfaces each extend across entire breadths of the first and second fin structures.

In example 18 the subject matter of examples 16-18 can optionally include wherein the first and second upper fin portions are included in first and second nanoribbons that are included in gate-all-around devices.

Example 19 includes a device comprising: first and second fins adjacent one another and each including channel and subfin layers, the channel layers having bottom surfaces directly contacting upper surfaces of the subfin layers; wherein (a) the bottom surfaces are generally coplanar with one another and are generally flat; (b) the upper surfaces are generally coplanar with one another and are generally flat; and (c) the channel layers include an upper III-V material and the subfin layers include a lower III-V material different from the upper III-V material.

In example 20 the subject matter of example 19 can optionally include wherein the first and second fins are at least partially included in trenches having generally equivalent aspect ratios (depth to width) that are at least 2:1.

In example 21 the subject matter of examples 19-20 can optionally include a semiconductor processing method comprising: wherein (a) the first fin include left and right end portions having left and right bottom surfaces that are coplanar with one another and generally parallel to a substrate included in the device.

In example 22 the subject matter of examples 19-21 can optionally include wherein the bottom surfaces extend across entire breadths of the first and second fins.

In example 23 the subject matter of examples 19-22 can optionally include wherein the channel layers are included in nanoribbons that are included in gate-all-around devices.

The foregoing description of the embodiments of the invention has been presented for the purposes of illustration and description. It is not intended to be exhaustive or to limit the invention to the precise forms disclosed. This description and the claims following include terms, such as left, right, top, bottom, over, under, upper, lower, first, second, etc. that are used for descriptive purposes only and are not to be construed as limiting. For example, terms designating relative vertical position refer to a situation where a device side (or active surface) of a substrate or integrated circuit is the “top” surface of that substrate; the substrate may actually be in any orientation so that a “top” side of a substrate may be lower than the “bottom” side in a standard terrestrial frame of reference and still fall within the meaning of the term “top.” The term “on” as used herein (including in the claims) does not indicate that a first layer “on” a second layer is directly on and in immediate contact with the second layer unless such is specifically stated; there may be a third layer or other structure between the first layer and the second layer on the first layer. The embodiments of a device or article described herein can be manufactured, used, or shipped in a number of positions and orientations. Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

What is claimed is:

1. A device comprising:
a first fin structure including a first upper fin portion on a first lower fin portion;
a second fin structure including a second upper fin portion on a second lower fin portion;
wherein (a) no other fin structures exist between the first and second fin structures and first and second fin structures are adjacent one another; (b) the first and second upper fin portions have first and second bottom surfaces that directly contact first and second upper surfaces of the first and second lower fin portions; (c) the first and second bottom surfaces are generally coplanar with one another and are generally flat; (d) the first and second upper surfaces are generally coplanar with one another and are generally flat; and (e) the first and second upper fin structures include an upper III-V material and the first and second lower fin structures include a lower III-V material different from the upper III-V material.

2. The device of claim 1, wherein the first and second fin structures are at least partially included in first and second trenches.

3. The device of claim 2, wherein the first and second trenches each have generally equivalent aspect ratios (depth to width) that are at least 2:1.

4. The device of claim 2, wherein the upper III-V material includes InₓGa₁₋ₓAs where x is between 0 and 1.

5. The device of claim 4, wherein the lower III-V material includes InP.

6. The device of claim 2, wherein the first and second upper fin structures and the first and second lower fin structures are epitaxial layers.

7. The device of claim 1 including a substrate, wherein the first and second bottom surfaces are generally parallel to a long axis of the substrate.

8. The device of claim 7, wherein (a) the first fin structure includes a left end portion at a left end of the first fin structure and a right end portion at a right end of the first fin structure; (b) the left end portion includes a left bottom surface portion of the first bottom surface and the right end portion includes a right bottom surface portion of the first bottom surface; and (c) the left and right bottom surface portions are coplanar with one another and generally parallel to the substrate.

9. The device of claim 7 wherein the first and second upper fin portions have first and second top surfaces that are generally coplanar with one another, are generally flat, and are generally parallel to the substrate and to the first and second bottom surfaces.

10. The device of claim 1, wherein the first and second bottom surfaces each extend across entire breadths of the first and second fin structures.

11. The device of claim 1, wherein the first and second upper fin portions are included in first and second nanoribbons.

12. The device of claim 11, wherein the first and second nanoribbons are included in gate-all-around devices.

13. A device comprising:
a first fin structure including a first upper fin portion on a first lower fin portion;
a second fin structure including a second upper fin portion on a second lower fin portion;
wherein (a) the first and second upper fin portions have first and second bottom surfaces that directly contact first and second upper surfaces of the first and second lower fin portions; (b) the first and second bottom surfaces are generally coplanar with one another and are generally flat; (c) the first and second upper surfaces are generally coplanar with one another and are generally flat; (d) the first and second upper fin structures include an upper III-V material and the first and second lower fin structures include a lower III-V material different from the upper III-V material; and (e) a first vertical axis intersects first portions of the first bottom surface and the first upper surface, a second vertical axis intersects second portions of the first bottom surface and the first upper surface, and a third vertical axis, located between the first and second vertical axes, intersects a third portions of the first bottom surface and a gate but no portion of the first upper surface.

14. The device of claim 13, wherein the first and second fin structures are at least partially included in first and second trenches that each have generally equivalent aspect ratios (depth to width) that are at least 2:1.

15. The device of claim 13 including a substrate, wherein the first and second bottom surfaces are generally parallel to a long axis of the substrate.

16. The device of claim 13, wherein (a) the first fin structure includes a left end portion at a left end of the first fin structure and a right end portion at a right end of the first fin structure; (b) the left end portion includes a left bottom surface portion of the first bottom surface and the right end portion includes a right bottom surface portion of the first bottom surface; and (c) the left and right bottom surface portions are coplanar with one another and generally parallel to the substrate.

17. The device of claim 13, wherein the first and second bottom surfaces each extend across entire breadths of the first and second fin structures.

18. The device of claim 13, wherein the first and second upper fin portions are included in first and second nanoribbons that are included in gate-all-around devices.

19. A device comprising:
first and second fins adjacent one another and each including channel and subfin layers, the channel layers having bottom surfaces directly contacting upper surfaces of the subfin layers;
wherein (a) the bottom surfaces are generally coplanar with one another and are generally flat; (b) the upper surfaces are generally coplanar with one another and are generally flat; and (c) the channel layers include an upper III-V material and the subfin layers include a lower III-V material different from the upper III-V material.

20. The device of claim 19, wherein the first and second fins are at least partially included in trenches having generally equivalent aspect ratios (depth to width) that are at least 2:1.

21. The device of claim 20, wherein (a) the first fin include left and right end portions having left and right bottom surfaces that are coplanar with one another and generally parallel to a substrate included in the device.

22. The device of claim 19, wherein the bottom surfaces extend across entire breadths of the first and second fins.

23. The device of claim 19, wherein the channel layers are included in nanoribbons that are included in gate-all-around devices.
